(19) United States
(12) Patent Application Publication
(10) Pub. No.: US 2023/0327438 A1
(43) Pub. Date: Oct. 12, 2023

(54) SCALABLE STATE ESTIMATION FOR POWER DISTRIBUTION GRID

(71) Applicant: GENERAL ELECTRIC COMPANY, Schenectady, NY (US)

(72) Inventors: Aditya Kumar, Schenectady, NY (US); Reza Ghaemi, Watervliet, NY (US); Michael Unum, Merritt Island, FL (US); Paul Kuntz, Spokane, WA (US); Ethan Clair Boardman, Seattle, WA (US)

(21) Appl. No.: 17/717,405

(22) Filed: Apr. 11, 2022

(51) Int. Cl. H02J 3/00; G01R 19/25

(52) U.S. Cl. CPC H02J 3/003; G01R 19/2513; H02J 2203/20

(57) ABSTRACT

Provided is a system and method for determining the state estimate of a power grid by dividing the power grid into smaller sub-sections, generating state estimates for each sub-section, and then generating a consensus among the sub-sections. In one example, the method may include partitioning a section of the power distribution grid into a plurality of sub-sections based on loads distributed within the section of the power distribution grid, generating a plurality of state estimates for the plurality of sub-sections based on load distribution within the plurality of sub-sections and a Kalman Filter model, generating an aggregate state estimate for the section of the power distribution grid based on an aggregate of the plurality of state estimates and a boundary consensus between the plurality of sub-sections from a previous state estimation, and displaying data about the aggregate state estimate via a user interface.

### BACKGROUND

System operators may manage a power distribution grid (“power grid”) from a set of computer consoles within a control center. The operators may be provided with interactive user interfaces via the computer consoles that enable the operators to make changes to a flow of power on the grid should there be a need. Traditionally, the analytical software derives power flow based on a Jacobian Matrix/Impedance Matrix. The analytic software takes all the known injections at various locations in the power grid and determines the resulting voltage, magnitudes, and angles at each node and uses them to compute the corresponding branch power flows during the process.

More recently, attempts have been made to introduce state estimation as an alternative to the use of power flow. A state estimator does not assume all input information. Here, measurement observations and the mathematical representation of electrical equipment can be used, but it has the ability to use redundant observations and relative information uncertainties to estimate the electrical state. It essentially acts as a large filter and looks at the implied accuracy of the measurements and attempts to minimize the error between the estimated and measured values of power on the grid. State estimation provides the ability to detect, identify and reject bad measurements as well as to estimate quantities not directly measured, thereby allowing grid operators to better understand the operational state of the power grid. State estimation for electrical transmission grids is quite mature and involves solving for the operational state of the network in its entirety in a single state estimation problem, typically once per minute. While they are standard issue in just about every transmission control room in the world, their operational usage in distribution has been extremely limited, due to a number of factors including limited numbers and types of measurements, less accurate measurements and the dynamic behavior of the distribution network and its massive scale as compared to transmission.

The degree of success attributable to state estimator techniques depends on a number of factors. For example, the measurements from the grid must be highly redundant (i.e., dense). A traditional rule of thumb is that an accurate state estimation needs 2N measurements where N is the number of unknowns to estimate state. It also requires that these measurements be distributed uniformly across the power grid, otherwise, portions of the grid will not be observable and the estimation will not be accurate. Where actual measurements are not available, lower quality pseudo-measurements are often used to complete the measurement set.

However, within the distribution grid, measurements are coming in at different frequencies so there is significant time skew in the measurements (e.g., some are acquired every few seconds while other measurements are only captured a couple of times an hour, etc.) Furthermore, the grid undergoes almost continuation evolution. New power sources and power consuming devices and systems are always being added to the grid which can reduce stability in the grid. Furthermore, when a storm occurs, electrical crews come in and make repairs to various elements on the grid that become damaged, and this can cause significant changes in the topology and electrical characteristics of the power grid. In addition, distributed energy sources are continually being added by grid customers which makes estimating the state of the grid even more difficult as their locations and characteristics are often not well known.

Recently, there has been a push to provide a real-time state estimation of a distribution power grid for enhanced safety and reliability. However, because of the drawbacks noted above, the state estimation process is particularly challenging. A large transmission system may have thousands of nodes in total, similar node counts are often associated with a single large distribution substation of which there may be hundreds or thousands. As the node count and the number of unknowns increase in size, the number of equations and the computation time for state estimation also increases. Attempting to solve a large distribution network as a single state estimation problem would involve a scale so vast as to likely introduce numerical ill conditioning rendering traditional solution methods non-viable. Furthermore, the elapsed-time to solve a traditional state estimation problem for a large power distribution grid is measured in hours. Accordingly, what is needed is an improved state estimation process that reliably delivers operationally relevant results in near real-time (e.g., within 30-60 seconds, etc.)

### SUMMARY

The example embodiments are directed to a state estimation process that can be performed in approximately the same amount of time regardless of a size of the power grid. Rather than execute a large power flow model, the present application divides the grid into a plurality of smaller partitions or sub-sections. Furthermore, a different type of state estimator (i.e., an unscented Kalman Filter model) can be used to perform local state estimates within the respective sub-sections using data that is acquired from the respective sub-sections. Furthermore, the individual state estimates may be combined through a consensus process that resolves state estimate differences along boundaries of adjacent sub-sections where each sub-section has a different state estimate for the boundary.

By dividing the power grid into smaller sub-sections, and then executing individual models on each of the sub-sections, it is possible to perform the state estimates of each sub-section in parallel (i.e., simultaneously) via a multi-core processor. Accordingly, the time that it takes to perform the state estimation for large power grids (e.g., over 10,000 nodes) can be comparable to the time it takes to perform a state estimation for smaller power grid). A state estimator builds upon the model and combined with measurements can provide state estimates. There are different variants of Kalman filters. The original Kalman filter was designed for linear systems. For nonlinear systems (like in the present application), nonlinear variants like “extended” Kalman filter or “unscented” Kalman filter can be used. As an example, an unscented Kalman filter (UKF) can be employed since it is more accurate in handling nonlinearities and avoids the challenge of linearizing the nonlinear model (as an extended Kalman filter would need). The reduced state-space makes the implementation of the Kalman filter more practical (the sizes of matrices, e.g., covariance matrices are manageable and less likely to be ill-conditioned). The reduced state space enables practical implementation of a Kalman filter with manageable size matrices (for memory and CPU needs) that also are less likely to be ill-conditioned (numerically).

In an aspect of an example embodiment, a computing system may include a memory configured to store data from a power distribution grid, and a processor configured to partition a section of the power distribution grid into a plurality of sub-sections based on loads distributed within the section of the power distribution grid, generate a plurality of state estimates for the plurality of sub-sections based on load distribution within the plurality of sub-sections and an unscented Kalman Filter estimator, and generate an aggregate state estimate for the section of the power distribution grid based on an aggregate of the plurality of state estimates for the plurality of sub-sections and a boundary consensus between the plurality of sub-sections from a previous state estimation of the section of the power distribution grid, and display data about the aggregate state estimate via a user interface.

In an aspect of an example embodiments, a non-transitory computer-readable storage medium may include instructions for a method that includes partitioning a section of the power distribution grid into a plurality of sub-sections based on loads distributed within the section of the power distribution grid, generating a plurality of state estimates for the plurality of sub-sections based on load distribution within the plurality of sub-sections and an unscented Kalman Filter estimator, and generating an aggregate state estimate for the section of the power distribution grid based on an aggregate of the plurality of state estimates for the plurality of sub-sections and a boundary consensus between the plurality of sub-sections from a previous state estimation of the section of the power distribution grid, and displaying data about the aggregate state estimate via a user interface.

Other features and aspects may be apparent from the following detailed description taken in conjunction with the drawings and the claims.

### BRIEF DESCRIPTION OF THE DRAWINGS

Features and advantages of the example embodiments, and the manner in which the same are accomplished, will become more readily apparent with reference to the following detailed description taken in conjunction with the accompanying drawings.

FIG. 1 is a diagram illustrating a power system for delivering electricity to a customer in accordance with an example embodiment.

FIG. 2 is a diagram illustrating a network topology of an electrical grid.

FIG. 3 is a diagram illustrating a system including an enhanced disturbance management (EDM) module.

FIGS. 4A-4C are diagrams illustrating a process of partitioning a power grid according to example embodiments.

FIGS. 5A-5C are diagrams illustrating a consensus process for a boundary state estimate in accordance with example embodiments.

FIG. 6 is a diagram illustrating a method of a partitioning a state estimation process in accordance with an example embodiment.

FIG. 7 is a diagram illustrating a computing system for use in the examples herein in accordance with an example embodiment.

Throughout the drawings and the detailed description, unless otherwise described, the same drawing reference numerals will be understood to refer to the same elements, features, and structures. The relative size and depiction of these elements may be exaggerated or adjusted for clarity, illustration, and/or convenience.

### DETAILED DESCRIPTION

In the following description, specific details are set forth in order to provide a thorough understanding of the various example embodiments. It should be appreciated that various modifications to the embodiments will be readily apparent to those skilled in the art, and the generic principles defined herein may be applied to other embodiments and applications without departing from the spirit and scope of the disclosure. Moreover, in the following description, numerous details are set forth for the purpose of explanation. However, one of ordinary skill in the art should understand that embodiments may be practiced without the use of these specific details. In other instances, well-known structures and processes are not shown or described in order not to obscure the description with unnecessary detail. Thus, the present disclosure is not intended to be limited to the embodiments shown but is to be accorded the widest scope consistent with the principles and features disclosed herein.

In the example embodiments, measurements obtained from the power grid may be used to perform a state estimation process as described herein. For example, data such as voltage, current, power flow, etc., measured at various points in the grid may be used as inputs to an unscented Kalman Filter (UKF) which generates a local state estimate for a respective sub-section of the grid.

Typically, a UKF is not used to perform a state estimate of a power distribution grid because of the size of such a grid, the density of the grid, and the number of unknowns. However, in the example embodiments, the state estimation process is broken-up into smaller sub-processes by partitioning the grid into smaller sub-sections and then estimating the state of the individual sub-sections using local UKFs for each sub-section. The local state estimates can then be combined via a consensus process that resolves differences in boundary estimates between adjacent sub-sections.

Because each sub-section on the grid may be significantly smaller than the entire grid, different types of models may be used that can be more accurate in situations where the loads are not as densely populated. The UKF works well in such a power environment. Therefore, by breaking-up the power grid into smaller sub-sections, a UKF can be used to accurately calculate the state estimate.

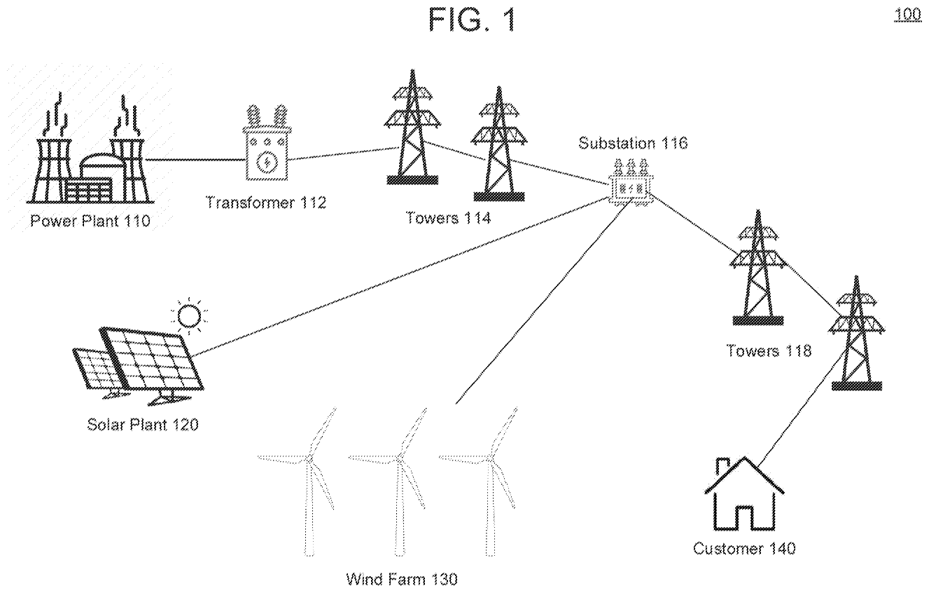

FIG. 1 illustrates a power delivery system 100 showing components that can facilitate the generation of power and the process of delivering power (e.g., delivering energy, electricity) to customer premises 140. Electric power can be generated at a power generation facility (power plant 110), passed to a transformer 112 and then carried by transmission power lines 114 to substations 116 having transformers. A local distribution system of smaller, lower-voltage transmission lines 118 and substations carry power to the customer premises 140. In the example of FIG. 1, the power delivery system 100 may also include renewable sources of power including a solar plant 120 and a wind farm 130. As in the case of the power plant 110, the solar plant 120 and the wind farm 130 can generate electric power which is passed to a point on the grid (e.g., substation 116, etc.) and carried to the customer premise 140 just as the power from the power plant 110. In operation, any of these sources, lines, or other components can be the cause of an oscillation in the power delivery system 100.

A variety of facilities can generate electric power including both power plants and renewable energy sources. For example, power generation facilities (e.g., power plant 110, etc.) can include power plants that burn coal, oil, or natural gas. As another example, power generation facilities can include nuclear power plants, renewable sources of energy (e.g., solar plant 120, wind farm 130, etc.) such as hydroelectric dams, wind turbines, and solar panels, and the like. The location of these power generation facilities, and their distance from end users, can vary widely.

The electricity that is generated by the power generation facilities may be stepped up or stepped down by transformers (e.g., transformer 112) which may be located at power plant substations adjacent to (and connected via power lines to) the power plant. For example, a transformer may be a step-up transformer that will “step up” the voltage of the electricity. When power travels through power lines (e.g., metallic wires that conduct electricity), some of that power is wasted in the form of heat. The power loss is proportional to the amount of current being carried. Power companies keep the current low and compensate by stepping up the voltage. After the voltage is stepped up, the electricity is typically carried over long distances by high voltage power transmission lines, typically supported and elevated by transmission towers (e.g., transmission towers 114 and 118) that can be of various dimensions, materials, and heights.

The voltage may be gradually reduced by step-down transformers as the electricity approaches customer premises. Transmission substations contain step-down transformers that reduce the voltage of the electricity. The electricity can then be distributed on lower-voltage power lines. A typical transmission substation can serve tens of thousands of customers. The electricity leaving transmission substations can travel through power lines to distribution substations. Distribution substations contain step-down transformers that further reduce the voltage of electricity and distribute the power with distribution, or branch, lines running through urban and rural areas. Distribution lines carry lower voltage power to clusters of homes and businesses, and are typically supported by wooden poles. Of note, power lines can also be buried under the ground. Of note, substations can contain a variety of other equipment, including switches, breakers, regulators, batteries, etc.

The voltage from a branch line can further be reduced by transformers that are mounted on poles that connect customer premises through a service drop power line. Customer premises (e.g., customer premise 140, etc.) can be of any type and variety. Customer premises can be a residential customer premises, such as residential houses. Customer premises can be an industrial customer premises, such as factories. Customer premises can be commercial customer premises, such as an office building. If a particular customer premises has a heavier load (e.g., has a higher demand for power), then a larger transformer, instead of a pole transformer, might service that particular customer premises.

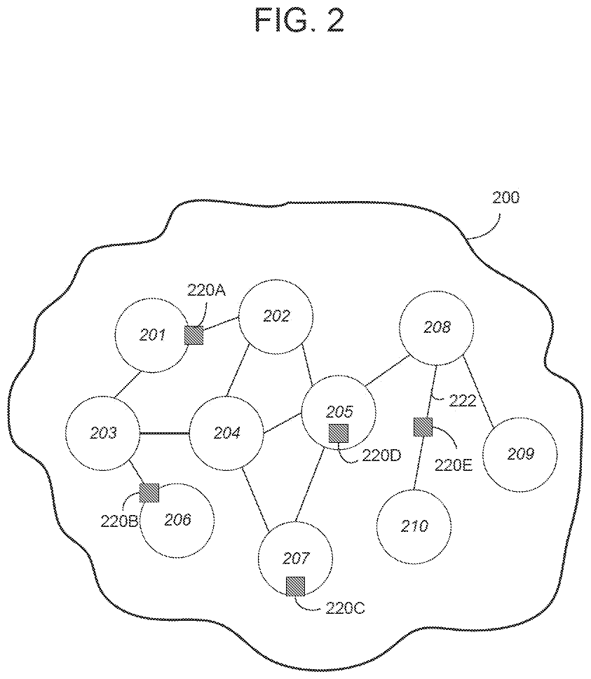

FIG. 2 depicts an illustration of a power grid system 200 (e.g., an electrical grid) comprising multitudes of nodes 201-210. In this example, a node may represent a power generation facility, transmission substation, a distribution substation, and the like, and is intended to convey that such facilities and substations can be interconnected. In the examples herein, a node may be referred to as a “power system node.” The power grid system 200 can follow a structural topology, influenced by factors such as budget, system reliability, load demand (demand for power), land, and geology. The structural topology in many cities and towns, for example many of those in North America, tends to follow a classic radial topology. This is a tree-shape network wherein power from larger voltage lines and substations radiates out into progressively lower voltage lines and substations until the customer premises are reached.

A substation receives its power from a power generation facility, and the power may be stepped down with a transformer and sent through lines that spread out in all directions across the countryside. These feeders carry three-phase power and tend to follow major streets near the substation. As the distance from the substation grows, the fanout continues as smaller laterals spread out to cover areas missed by the feeders. This tree-like structure grows outward from the substation, but a single power failure can render inoperable entire branches of the tree. For reliability reasons, there are often unused backup connections from one substation to a nearby substation. This backup connection can be enabled in case of an emergency, such that a part of a substation's service area can be fed by another substation in case of any power failure events. Redundancy allows line failures to occur and power to be rerouted while workmen restore to service damaged or deactivated components. Neighboring power utilities also typically link their grids, thereby assisting one another to maintain a balance between power generation supply and loads (e.g., customer demand). Other topologies can be mesh topologies, looped systems (mostly found in Europe) and ring networks.

The result can be an interconnected power grid system 200 that can form complex networks of power plants and transformers connected by hundreds of thousands of miles of high-voltage transmission lines. While these interconnections can be useful in situations, the danger or risk can comprise the possibility that a shutdown in one sector could rapidly spread to other sectors, leading to massive power failures in a wide area.

In the example of FIG. 2, disposed within the power grid system 200 are measurement devices 220A-220E. Throughout a power network, a variety of sensors, monitoring devices and measurement devices (collectively referred to herein as “measurement devices”) can be located at one or more nodes (e.g., nodes 201-210), in between nodes on lines, and the like, and can be used to provide monitoring data related to power flow measurements, or monitor the condition of one or more aspects of a power grid system. The measurement devices 220A-220E may be deployed within, or adjacent to, power transmission components (e.g., generating units, transformers, circuit breakers), including at substations. In some examples, the measurement devices 220A-220E can also be deployed along distribution lines.

The measurement devices 220A-220E may include sensors that measure a range of parameters such as magnitude and phase angle of voltage, current, harmonic distortion, real and reactive power, power factor, and fault current. Examples of some sensors include, but are not limited to, voltage and current sensors, PMUs, transformer-Metal Insulated Semiconducting (MIS) gas in oil sensors, circuit breaker sulfur hexafluoride density sensors, conductor temperature and current sensors that record overhead transmission conductor temperatures and current magnitudes, overhead insulator leakage current sensors, Transmission Line Surge Arrester (TLSA) sensors, and the like.

In the example of FIG. 2, the power grid system 200 may include the measurement devices 220A-220E located in various parts (e.g., such as nodes) throughout the grid. The measurement devices 220A-220E can be coupled via a network of transmission lines, as well as through wireless and wired communications mediums (e.g., cellular, ethernet, etc.). For example, a measurement device 220E can be coupled via a transmission line 222 from a network of transmission lines associated with the nodes 201-210. Furthermore, a subset of the measurement devices can be associated with a sector of the power grid system 200.

In example embodiments, the reliability of the power grid system 200 can be facilitated through the use and analysis of the data received from measurement devices 220A-220E and monitoring of system conditions that are then communicated to a central control center, where a combination of automated actions and human decision assist in striving to ensure that the power grid system 200 is stable and balanced. For example, a measurement device may include a phasor measurement unit (PMU) which can capture data of a disturbance event. PMUs typically have a naming convention based on PMU information which is defined by a regional transmission authority. Meanwhile, power system nodes 201-210 have a naming convention based on utility companies. As a result, the measurement devices 220A-220E may have names that are not identical to or correlated with the names of the power system nodes 201-210. As further described herein, the system can perform automated tag mapping to correlate the measurement devices 220A-220E with corresponding power system nodes 201-210.

Among other operations, described herein is an Enhanced Disturbance Management (EDM) component (e.g., module) that is operable to read (e.g., obtain) monitoring data, for example, Supervisory Control and Data Acquisition (SCADA) system data, PMU-based data, topology data, and the like, based on power flow measurements associated with measurement devices (e.g., PMUs, current sensors, voltage sensors, etc.) connected to an electrical power system (e.g., electric power system, electrical energy system, electric energy system, power grid system, etc.), wherein the monitoring data can comprise alarm data indicative of an electrical disturbance within the electrical power system, and topology data indicative of a topology of the electrical power system. The EDM component can be operable to correlate the alarm data, which can relate to, for example, an angle disturbance alarm, or, for example, a frequency disturbance alarm, with a change in the topology data.

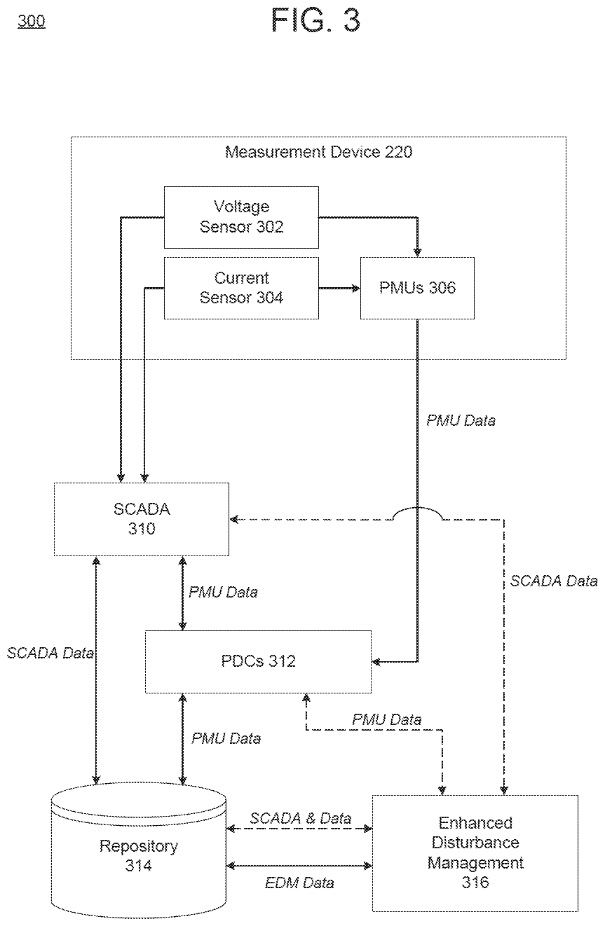

FIG. 3 illustrates a system 300 including an EDM module 316 in accordance with an example embodiment. In this example, the EDM module 316 can determine a characterization (e.g., classification, causation) of the electrical disturbance in the power grid system based on the correlating of the alarm data with the topology data, determining a coherency level representative of the degree of correlation between the alarm data and the topology data, determining a Disturbance Impact Factor (DIF) indicative of an impact of the electrical disturbance on a location in the power grid system, and identify one or more sensors (PMUs) that have captured data of the disturbance. The EDM module 316 can further auto-map PMUs to one or more power system nodes on the grid, retrieve power model information of the power system nodes, and validate the retrieved power model based on the PMU information of the disturbance. In some embodiments, the EDM module 316 can also store and display disturbance history, event history, and a variety of other statistical information related to disturbances and events, including on a graphical user interface, or in a generated report.

Measurement device 220 in FIG. 3 can obtain, monitor or facilitate the determination of electrical characteristics associated with the power grid system (e.g., the electrical power system), which can comprise, for example, power flows, voltage, current, harmonic distortion, frequency, real and reactive power, power factor, fault current, and phase angles. Measurement device 220 can also be associated with a protection relay, a Global Positioning System (GPS), a Phasor Data Concentrator (PDC), communication capabilities, or other functionalities.

Measurement devices 220 can provide real-time measurements of electrical characteristics or electrical parameters associated with the power grid system (e.g., the electrical power system). The measurement device 220 can, for example, repeatedly obtain measurements from the power grid system (e.g., the electrical power system) that can be used by the EDM module 316. The data generated or obtained by the measurement device 220 can be coded data (e.g., encoded data) associated with the power grid system that can input (or be fed into) a traditional SCADA/EDM system.

In the example of FIG. 3, the measurement device 220 includes a voltage sensor 302 and a current sensor 304 that feed data typically via other components, to, for example, a Supervisory Control and Data Acquisition (SCADA) system (e.g., SCADA component 310). Voltage and current magnitudes can be measured and reported to a system operator every few seconds by the SCADA component 310. The SCADA component 310 can provide functions such as data acquisition, control of power plants, and alarm display. The SCADA component can also allow operators at a central control center to perform or facilitate management of energy flow in the power grid system. For example, operators can use a SCADA component (for example using a computer such as a laptop or desktop) to facilitate performance of certain tasks such as opening or closing circuit breakers, or other switching operations that might divert the flow of electricity.

In some examples, the SCADA component 310 can receive measurement data from Remote Terminal Units (RTUs) connected to sensors in the power grid system, Programmable Logic Controllers (PLCs) connected to sensors in the power grid system, or a communication system (e.g., a telemetry system) associated with the power grid system. PLCs and RTUs can be installed at power plants, substations, and the intersections of transmission and distribution lines, and can be connected to various sensors, including the voltage sensor 302 and the current sensor 304. The PLCs and RTUs receive its data from the voltage and current sensors to which they are connected. The PLCs and RTUs can convert the measured information to digital form for transmission of the data to the SCADA component. In example embodiments, the SCADA component 310 can also comprise central host server or servers called master terminal units (MTUs), sometimes also referred to as a SCADA center. The MTU can also send signals to PLCs and RTUs to control equipment through actuators and switchboxes. In addition, the MTU can perform controlling, alarming, and networking with other nodes, etc. Thus, the SCADA component 310 can monitor the PLCs and RTUs, and can send information or alarms back to operators over telecommunications channels.

The SCADA component 310 can also be associated with a system for monitoring or controlling devices in the power grid system, such as an Energy Management System (EMS). An EMS can comprise one or more systems of computer-aided tools used by operators of the electric power grid systems to monitor, control, and optimize the performance of the generation or transmission system. Often, an EMS is also referred to as SCADA/EMS or EMS/SCADA. In these respects, the SCADA/EMS or EMS/SCADA can also perform the functions of a SCADA. Or, a SCADA can be operable to send data (e.g., SCADA data) to the EMS, which can in turn provide the data to the EDM module 316. Other systems with which the EDM module 316 can be associated can comprise a situational awareness system for the power grid system, a visualization system for the power grid system, a monitoring system for the power grid system or a stability assessment system for the power grid system.

The SCADA component 310 can generate or provide SCADA data (e.g., SCADA DATA shown in FIG. 3) comprising, for example, real-time information (e.g., real-time information associated with the devices in the power grid system) or sensor information (e.g., sensor information associated with the devices in the power grid system) that can be used by the EDM module 316. The SCADA data can be stored, for example, in a repository 314 (described further below). In example embodiments, data determined or generated by the SCADA component 310 can be employed to facilitate generation of topology data (topology data is further described below) that can be employed by the EDM module 316 for enhanced disturbance management, which is further described below.

The employment of current sensor 304 and voltage sensor 302 allow for fast response. Traditionally, the SCADA component 310 monitors power flow through lines, transformers, and other components relies on the taking of measurements every two to six seconds, and cannot be used to observe the dynamic characteristics of the power system because of its slow sampling rate (e.g., cannot detect the details of transient phenomena that occur on timescales of milliseconds (one 60 Hz cycle is 16 milliseconds). Additionally, although SCADA technology enables some coordination of transmission among utilities, the process can be slow, especially during emergencies, with much of the response based on telephone calls between human operators at the utility control centers. Furthermore, most PLCs and RTUs were developed before industry-wide standards for interoperability were established, and as such, neighboring utilities often use incompatible control protocols.

The measurement device 220 also includes one or more PMUs 306. A PMU 306 can be a standalone device or may be integrated into another piece of equipment such as a protective relay. PMUs 306 can be employed at substations, and can provide input into one or more software tools (e.g., WAMS, SCADA, EMS, and other applications). A PMU 306 can use voltage and current sensors (e.g., voltage sensors 302, current sensors 304) that can measure voltages and currents at principal intersecting locations (e.g., substations) on a power grid using a common time source for synchronization, and can output accurately time-stamped voltage and current phasors. The resulting measurement is often referred to as a synchrophasor (although the term synchrophasor refers to the synchronized phasor measurements taken by the PMU 306, some have also used the term to describe the device itself). Because these phasors are truly synchronized, synchronized comparison of two quantities is possible in real time, and this time synchronization allows synchronized real-time measurements of multiple remote measurement points on the grid.

In addition to synchronously measuring voltages and currents, phase voltages and currents, frequency, frequency rate-of-change, circuit breaker status, switch status, etc., the high sampling rates (e.g., 30 times a second) provides “sub-second” resolution in contrast with SCADA-based measurements. These comparisons can be used to assess system conditions-such as: frequency changes, power in megawatts (MW), reactive power in mega volt ampere reactive (MVARs), voltage in kilovolts (KV), etc. As such, PMU measurements can provide improved visibility into dynamic grid conditions and can allow for real-time wide area monitoring of power system dynamics. Further, synchrophasors account for the actual frequency of the power delivery system at the time of measurement. These measurements are important in alternating current (AC) power systems, as power flows from a higher to a lower voltage phase angle, and the difference between the two relates to power flow. Large phase angle differences between two distant PMUs can indicate the relative stress across the grid, even if the PMUs are not directly connected to each other by a single transmission line. This phase angle difference can be used to identify power grid instability, and a PMU can be used to generate an angle disturbance alarm (e.g., angle difference alarm) when it detects a phase angle difference.

Examples of disturbances that might cause the generation of an angle disturbance alarm can comprise, for example, a line out or line in disturbance (e.g., a line out disturbance in which a line that was in service has now gone out of service, or in the case of a line in disturbance, in which case a line that was out of service has been brought back into service). PMUs 306 can also be used to measure and detect frequency differences, resulting in frequency alarms being generated. As an example, unit out and unit in disturbances can result in the generation of a frequency alarm (e.g., a generating unit was in service, but might have gone out of service, or a unit that was out of service has come back into service—both can cause frequency disturbances in the system that can result in the generation of a frequency alarm.). Still yet, PMUs 306 can also be used to detect oscillation disturbances (e.g., oscillation in the voltage, frequency, real power—any kind of oscillation), which can result in the generation of an alarm (e.g., oscillation alarm). Several other types of alarms can be generated based on PMU data from PMU based measurements. Although the disturbances mentioned (e.g., line in/out, unit in/out, load in/out) can result in angle or frequency disturbance alarms, an angle or frequency disturbance alarm might not necessarily mean that a particular type of disturbance occurred, only that it is indicative of that type of disturbance. For example, if a frequency disturbance alarm is detected, it might not necessarily be a unit in or unit out disturbance, but may be a load in or load out disturbance. The measurement requirements and compliance tests for a PMU 306 have been standardized by the Institute of Electrical and Electronics Engineers (IEEE), namely IEEE Standard C37.118.

In the example of FIG. 3, one or more Phasor Data Concentrators (PDCs) 312 are shown, which can comprise local PDCs at a substation. Here, PDCs 312 can be used to receive and time-synchronized PMU data from multiple PMUs 306 to produce a real-time, time-aligned output data stream. A PDC can exchange phasor data with PDCs at other locations. Multiple PDCs can also feed phasor data to a central PDC, which can be located at a control center. Through the use of multiple PDCs, multiple layers of concentration can be implemented within an individual synchrophasor data system. The PMU data collected by the PDC 312 can feed into other systems, for example, a central PDC, corporate PDC, regional PDC, the SCADA component 310 (optionally indicated by a dashed connector), energy management system (EMS), synchrophasor applications software systems, a WAMS, the EDM module 316, or some other control center software system. With the very high sampling rates (typically 10 to 60 times a seconds) and the large number of PMU installations at the substations that are streaming data in real time, most phasor acquisition systems comprising PDCs are handling large amounts of data. As a reference, the central PDC at Tennessee Valley Authority (TVA), is currently responsible for concentrating the data from over 90 PMUs and handles over 31 gigabytes (GBs) of data per day.

In this example, the measurement device 220, the SCADA component 310, and PDCs/Central PDCs 312, can provide data (e.g., real-time data associated with devices, meters, sensors or other equipment in the power grid system) (including SCADA data and topology data), that can be used by the EDM module 316 for enhanced disturbance management. Both SCADA data and PMU data can be stored in one or more repositories 3014. In some example embodiments, the SCADA data and PMU data can be stored into the repository 314 by the SCADA component 310, or by the PDC 412. In other embodiments, the EDM module 316 can have one or more components or modules that are operable to receive SCADA data and PMU data and store the data into the repository 314 (indicated by dashed lines). The repository can comprise a local repository, or a networked repository. The data on the repository 314 can be accessed by SCADA component 310, the PDCs 312, other systems (not shown), and optionally by example embodiments of the EDM module 316. In example embodiments, the EDM module 316 can be operable to send instructions to one or more other systems (e.g., SCADA component 310, PDCs 312) to retrieve data stored on the repository 314 and provide it to the EDM module 316. In other embodiments, the EDM module 316 can facilitate retrieval of the data stored in repository 314, directly.

The data stored in the repository 314 can be associated SCADA data and PMU data. The data can be indicative of measurements by measurement device 220 that are repeatedly obtained from a power grid system. In example embodiments, the data in repository 314 can comprise PMU/SCADA-based equipment data, such as, for example, data associated with a particular unit, line, transformer, or load within a power grid system (e.g., power grid system 200). The data can comprise voltage measurements, current measurements, frequency measurements, phasor data (e.g., voltage and current phasors), etc. The data can be location-tagged. For example, it can comprise a station identification of a particular station in which a power delivery device being measured is located (e.g., “CANADA8”). The data can comprise a particular node number designated for a location. The data can comprise the identity of the measure equipment (e.g., the identification number of a circuit breaker associated with an equipment). The data can also be time-tagged, indicating the time at which the data was measured by a measurement device. The PMU/SCADA-based equipment data can also contain, for example, information regarding a particular measurement device (e.g., a PMU ID identifying the PMU from which measurements were taken).

The data stored in repository 314 can comprise not only collected and measured data from various measurement devices 220, but also data derived from that collected and measured data. The data derived can comprise topology data (e.g., PMU/SCADA-based topology data), event data, and event analysis data, and EDM data (data generated by EDM module 316).

The repository 314 can contain topology data (e.g., PMU/SCADA-based topology data) indicative of a topology for the power grid system 200. The topology of a power grid system can relate to the interconnections among power system components, such as generators, transformers, busbars, transmission lines, and loads. This topology can be obtained by determining the status of the switching components responsible for maintaining the connectivity status within the network. The switching components can be circuit breakers that are used to connect (or disconnect) any power system component (e.g., unit, line, transformer, etc.) to or from the rest of the power system network. Typical ways of determining topology can be by monitoring of the circuit breaker status, which can be done using measurement devices and components associated with those devices (e.g., RTUs, SCADA, PMUs). It can be determined as to which equipment has gone out of service, and actually, which circuit breaker has been opened or closed because of that equipment going out of service.

The topology data can be indicative of an arrangement (e.g., structural topology, such as radial, tree, etc.) or a power status of devices in the power grid system. Connectivity information or switching operation information originating from one or more measurement devices 220 can be used to generate the topology data. The topology data can be based on a location of devices in the power grid system, a connection status of devices in the power grid system or a connectivity state of devices in the power grid system (e.g., devices that receive or process power distributed in throughout the power grid system, such as transformers and breakers). For example, the topology data can indicate where devices are located, and which devices in the power grid system are connected to other devices in the power grid system (e.g., where devices in the power grid system are connected, etc.) or which devices in the power grid system are associated with a powered grid connection. The topology data can further comprise the connection status of devices (e.g., a transformer, etc.) that facilitate power delivery in the power grid system, and the statuses for switching operations associated with devices in the power grid system (e.g., an operation to interrupt, energize or de-energize or connect or disconnect) a portion of the power grid system by connecting or disconnecting one or more devices in the power grid system (e.g., open or close one or more switches associated with a device in the power grid system, connect or disconnect one or more transmission lines associated with a device in the power grid system etc.). Furthermore, the topology data can provide connectivity states of the devices in the power grid system (e.g., based on connection points, based on busses, etc.).

The repository 314 can contain a variety of event and event analysis data, which can be derived based on PMU data, and in some embodiments, other data as well (e.g., SCADA data, other measurement data, etc.). The data can comprise information regarding events related to the power grid system 200. An event can comprise, for example, one or more disturbances to the power grid system. A disturbance can comprise, for example, a line disturbance (e.g., line in, or line out), a unit disturbance (e.g., unit in or unit out), or load disturbance (load in or load out). For each event, relevant information such as the station where the event occurred, the voltage level associated with the station (e.g., 500 kV), the node number related to the event, the equipment related to the event, the change in real and reactive power, and change in voltage per unit for the event. The event and event analysis data can also comprise EDM data, which can be data related to events. The various data stored in the repository 314, including equipment data, topology data, event data, event analysis data, EDM data, and other data, can be inputs into the various functionalities and operations that can be performed by the EDM module 316.

A power distribution grid is used to provide electric power to end-customers, where voltages from a transmission grid are reduced and regulated through a series of transformers to achieve levels of power that are adequate for a customer's residence or place in business. In the presence of dynamically changing loads and resulting voltages and power flows, a state estimate of the power distribution grid state is important for online monitoring as well as for model-based control and optimization. In traditional approach, historic load profiles are used for grid planning, forecasting, state estimation, and control scheduling. However, as the power distribution grid evolves and becomes more complex with the addition of heterogeneous loads and distributed energy resources (DERs) including and electric vehicles and other sources of renewable energy, historical load profiles have become unreliable for purposes of grid state estimation. This increasing complexity of the power distribution grid, coupled with sparse online measurements (i.e., limited measurements in number, location and attribute) within the power grid make the state estimation of the power grid an increasingly more challenging problem.

Estimation approaches based on Kalman filtering, are widely used for online dynamic state estimation of industrial systems. Kalman filters provide online state estimation over time through recursive solution of maximum likelihood problem based on evolving statistics of modeling errors compared to individual measurement errors. A key aspect is to include the element of time and thus include state variation (in this case unknown loads) over time, and thus use successive measurements over time to get more accurate state estimates. This is especially true for nonlinear systems, where variation over time and the nonlinearity of the system can help improve overall system observability, compared to static estimation at each time instant.

While nonlinear variants of Kalman filter, e.g. extended Kalman filter (EKF) and unscented Kalman filter (UKF) are quite mature and widely used in industrial applications, they are not used in grid estimation. Traditional grid state estimators rely on weighted least square or least absolute value approach. Recently, loads forecast information and real-time measurements are used to estimate states based on Bayesian estimation schemes. These methods address state estimation in a “centralized” approach. However, one challenge is the sheer scale of a distribution grid with tens of thousands or more nodes and varying loads. Such a large-scale system imposes fundamental limitations on the use of a centralized approach to gather the necessary measurements in the grid and estimate all the unknown states in one central implementation. Similarly, for a centralized Kalman filter, the large size of the overall state vector and corresponding covariance matrix along with solution of large grid model would be practically impossible to use in real-time applications. For instance, the IEEE 8500 node reference grid has approximately 1200 unknown loads with a corresponding 2400 unknown active and reactive powers to estimate for a single feeder. These challenges will only grow as one seeks to perform state estimation for larger sections of the distribution grid. In contrast, ‘distributed” estimation approaches are more scalable.

Recently, distributed recursive least squares and Kalman filtering have been suggested to estimate the states of a system with a network of sensors. In this approach, it is assumed that each sensor or group of sensors maintains an estimate of the “full” state of the system as well as the error covariance matrix using the full dynamic model of the system. While this may be feasible for linear systems, this is not viable for nonlinear distribution grid where the full state vector could be several orders of magnitude larger than the number of local measurements. The key problem of excessive computation burden in a centralized estimation will be replicated in each local agent in such an approach. Also, there is no reason to estimate the full state vector for the entire grid in each section, which would anyway be unobservable from the sparse local measurements in the section.

In the example embodiments, a power system software application, such as those disposed inside control rooms and used by system operations, may be integrated with a state estimation method based on a distributed unscented Kalman filter (UKF) method that is scalable, assumes sparse grid measurement and requires limited communications. The method partitions a distribution grid into smaller sections, wherein each section has its own dedicated local UKF. The local UKF is based on the model of only the specific section, uses only on its local measurements and estimates only the local states in that section.

However, without any coordination between the individual UKFs, i.e., a decentralized solution, the estimates would be incorrect since they ignore the grid state in other sections. In particular, neighboring sections have significant interaction through power flows across the boundary nodes between the sections, which should be accounted for in correct estimation of the states of the overall grid. To address this coordination, UKFs in neighboring sections also include a joint consensus estimation of the mutual boundary conditions (voltages and power flow at the boundary nodes) which are then coupled as virtual measurements along with real measurements in each individual UKF. This provides exchange of information through the estimation of the boundary conditions between UKFs in neighboring sections, that converge to a common boundary condition estimate and thus, the overall state estimate. The equality of the boundary conditions from each neighboring section is thus enforced in each section via virtual assignments. Another approach would be to estimate the full state vector for all sections and then perform projection of the equality constrained subspace. In contrast, the example embodiments avoid estimation of the full state and covariance, which as mentioned is impractical given the size of the entire grid.

For example, a network topology may be represented by a graph [symbol] :=( [symbol] , ε), where the set of buses (or nodes) are represented by [symbol] with |V|=N and the set of lines are represented by [symbol] . Here, a line connecting two buses i and j is denoted by ijϵ [symbol] . Let rᵢⱼ and xᵢⱼ denote resistance and reactance of the line ij. The circuit model of the power system network is derived by replacing all the line and transformers with their equivalent model. Let yid be the mutual admittance between buses k and l and yₖₖ be the admittance between bus k and ground. Here, the admittance matrix of the equivalent circuit is denoted with Y where off-diagonal terms of negative mutual admittance and diagonal terms are negative sum of all off-diagonal terms plus the corresponding bus to ground admittance. Letting V be the column vector of complex bus voltages, the current vector I:=Y V is the vector of complex currents injected at each bus. Assuming S₁ the vector of complex power injected at the bus k, the following equation is generated:

Sₖ=VI*,Sₖ=(Pₖ^{g}−Pₖ^{l})+(Qₖ^{g}−Qₖ^{l})i Equation (1)

In this example, Pₖ^{g} and Qₖ^{g} are active and reactive powers generated (if the bus is connected to some generation source) and Pₖ^{l} and Qₖ^{l} are active and reactive loads at bus k. The above power flow equations are nonlinear between powers and voltages and different soft wares are introduced to solve PF equations. The voltage magnitude and voltage angle at the feeder is assumed to be known. Assuming all the loads active and reactive powers and generators power factors and active powers are known all the voltage and angles at all buses can be calculated and subsequently line power flows are determined. The loads may be assumed as unknown parameters whose statistics are updated via voltage magnitude and power measurements throughout distribution grid. This is elaborated in the next section.

It is assumed the feeder voltage magnitude and angle is given as Vo with the angle θ₀. Here, let Φ:=[P₁^{l}, Q₁^{l}, . . . , P_{N}_{ₗ}^{l}, Q_{N}_{ₗ}^{l}]ϵ [symbol] ^{N}^{ₚ} be the unknown parameter vector that is obtained by concatenating active and reactive power of all loads. If the loads are connected to three phases at the kth bus, then Pₖ^{l}ϵ [symbol] ³ and Qₖ^{l}ϵ [symbol] ³. These parameters Φ are time-varying and denoted as Φₖ at any sample k. The aim of the estimator is to use the time-varying measurements (e.g., voltage and/or current magnitudes, active power, reactive power, etc., at a few buses and lines, etc.) to estimate Φₖ. To this end, a non-linear map for the measurements from a state power flow model:

yₖ^{m}=h(uₖ,Φₖ) Equation (2)

The power flow model is augmented with a random walk model for the parameter variation (a random walk model is a general model allowing for unknown variation over time).

Φₖ₊₁=Φₖ+wₖ Equation (3)

To obtain a corresponding state-space model:

Φₖ₊₁=Φₖ+wₖ

yₖ^{m}=h(uₖ,Φₖ)+vₖ Equation (4)

where at each sample time Φₖ parameters become the dynamic states to be estimated, uₖ denotes the vector of known input variables (e.g., control settings from transformer tap changers, measured power injection from any generators), wₖ is white Gaussian noise and Φ₀ϵ [symbol] ^{N}^{ₚ} denotes the initial value of parameters that is a Gaussian random variable. The information about statistics of these variables are

E(wₖ)=0,E(wₖw′ₗ)=C_{w}δₖₗ,Φ₀= [symbol] (Φ̅₀,C_{Φ0}) Equation (5)

where C_{w}ϵ [symbol] ^{N}^{ₚ}^{×N}^{ₚ} and C_{Φ0}ϵ [symbol] ^{N}^{ₚ}^{×N}^{ₚ} are covariance matrices and Φ̅₀ denotes the initial mean value of the parameters. Similarly, y_{m,k}ϵ [symbol] ^{N}^{ₘ} denotes the vector of grid measurements at time sample k. The grid circuit model outlined in previous section provides a nonlinear map h: [symbol] ^{N}^{ₚ}→ [symbol] ^{N}^{ₘ} from parameters space to measurement space. All measurements are affected by noise vk which is assumed Gaussian with the statistics:

E(vₖ)=0,E(vₖv′ₗ)=Cᵥδₖₗ Equation (6)

where Cᵥϵ [symbol] ^{N}^{ₘ}^{×N}^{ₘ} is the covariance for measurement noise. Given the measurements up to time k, i.e., [symbol] ₖ:={Y₀, . . . , Yₖ}, a recursive nonlinear estimator can be used to obtain both the mean and the covariance of the parameter estimates:

Φₖ=E(Φₖ| [symbol] ₖ),C_{Φk}=E(ΦₖΦ′ₖ| [symbol] ₖ) Equation (7)

In the example embodiments, an unscented Kalman filter (UKF) can be used to estimate local state estimates of the individual sub-sections of the grid that are partitioned from a larger section of the grid. The UKF relies only on nonlinear simulation of the model without needing online linearization as in an extended Kalman filter (EKF) and is more accurate at addressing model nonlinearity. As an example, a spherical simplex version of the UKF may be used which enables using Np+2 points based on the Gaussian distribution instead of 2Np+1 points to perform the propagation and measurement update at each time sample k.

That is, the spherical simplex UKF needs to simulate the power flow model Np+2 times at each time sample to update the parameter estimate statistics (mean and covariance) recursively. While for moderate size grids (e.g., the IEEE 123 node system) this is viable to implement in a centralized estimator, such an approach rapidly become impractical for larger grids with thousands of nodes and unknown loads—the repeated execution or a large grid model becomes prohibitively expensive, and additionally the covariance matrix C_{Φk} becomes huge and potentially ill-conditioned. Such a centralized estimation approach is neither practical, nor scalable. Therefore, in the next section, provided is a distributed estimation scheme that makes estimation of large-scale distribution grid computationally feasible and scalable.

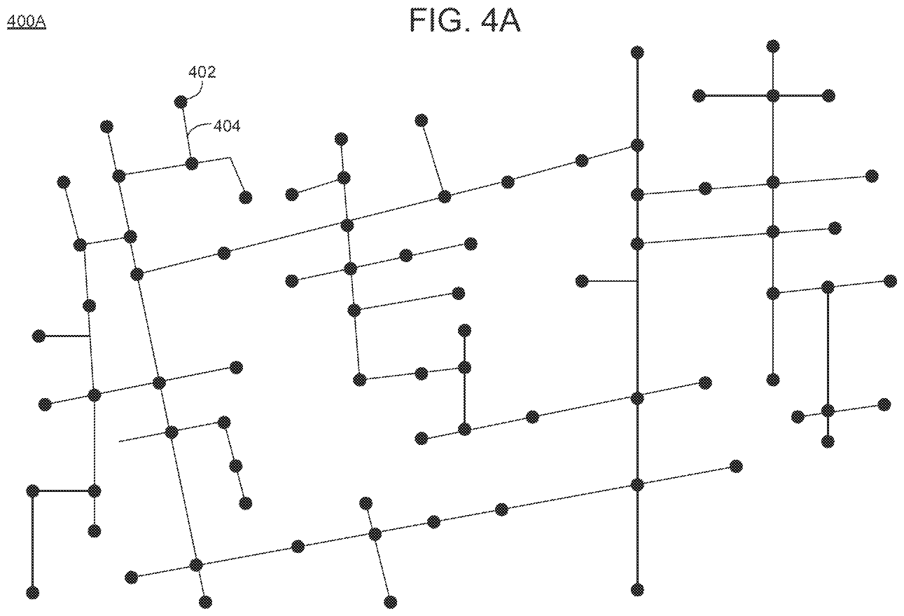

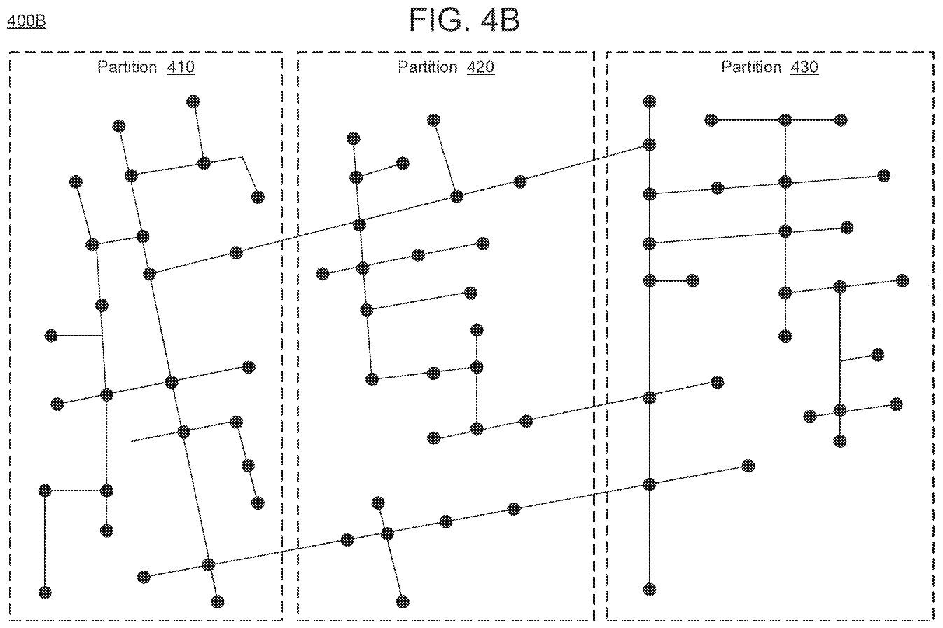

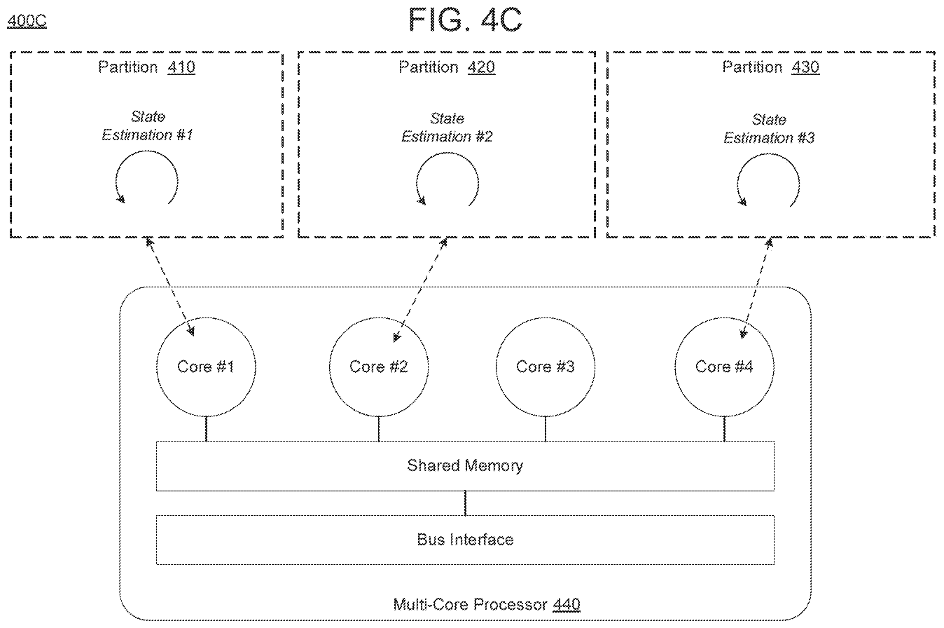

FIGS. 4A-4C illustrate a process of partitioning a power grid according to example embodiments. The aim of partitioning the grid is to divide the overall grid into smaller, more manageable sizes (i.e., based on the number of loads and states to be estimated in the section of the grid), where all partitions are comparable in load and state sizes. This allows the UKF for each partition to be well-conditioned and execute fast enough for the desired update rate. Also, a balanced size across partitions allows exploiting comparable UKF execution times for each partition, when the partition-specific UKFs are updated in parallel on a multi-core CPU.

For example, the power distribution grid may be divided or otherwise partitioned into sub-grids or sub-sections that are smaller in size than the overall power grid. Furthermore, the overall grid parameter estimates may also be updated according to a distributed iterative estimation scheme. For example, let buses i and j connected by a line ij be candidates for partitioning the grid into two sections A and B. In the partitioning performed in the example embodiments, the partitioning may be performed at buses, not lines. In light of this, a convention that bus i is included in A and a virtual bus i0 is introduced to keep the updated line i0j and bus j in partition B. In this example, the grid is partitioned into sub-sections A and B at a bus i.

In general, there could be multiple such boundary buses depending on the grid topology, and one could create as many partitions as needed to achieve reasonable size partitions. Any devices (loads, generators etc.) at each bus are retained in the respective partition, i.e., bus i0 doesn't have any of the original devices at bus i. One can readily implement a UKF in each partition to estimate the corresponding unknown loads, as described in previous section. However, without any coordination between the UKFs in each section, i.e., a decentralized architecture, they would lead to erroneous estimates. More specifically, a key requirement is to ensure continuity of voltage and power flow boundary constraints at the boundary buses i and i0, i.e.:

V_{A,i}=V_{B,i′}

P_{A,i}=−P_{B,i′},Q_{A,i}=−Q_{B,i′} Equation (8)

These boundary conditions will ensure that the power flow calculations in each partition are the same as in the original full grid before partitioning. To facilitate the enforcement of these boundary conditions, a virtual load l_{A,i} is implemented in partition A at bus i to denote the active and reactive power flows P_{A,i}, Q_{A,i}, respectively. Similarly, assuming the original voltage source is in partition A, a virtual voltage source VS_{B,i′} is added at bus i0 in partition B to denote the voltages V_{B,i′} (magnitude and angle) and resulting power) flows P_{B,i′}, Q_{B,i′} needed for the boundary constraints. Note that the new virtual load in partition A and voltage source in partition B have unknown active and reactive power flows and voltage magnitude and angles respectively, to be estimated dynamically (for each phase).

Referring to FIG. 4A, a view 400A of a power grid is shown. In this example, loads 402 are represented by dots or other objects and lines 404 interconnecting the loads 402 are used to represent wires (e.g., copper, etc.) on the power grid. Here, the power grid may include a country, a state, a city, or the like. Such large-scale power grids make state estimation difficult, especially for any systems/sub-systems that rely on real-time data.

FIG. 4B illustrates a view 400B of the power grid shown in the view 400A of FIG. 4A, except that the system has divided the power grid into a plurality of partitions 410, 420, and 430, based on distributions of loads within the power grid. Here, the partitioning function may use a couple of attributes to find the ideal/optimal number of partitions. For example, each partition may be limited in the number of loads that can be included therein, for example, by a predetermined load limit/threshold. This ensures that the UKF can operate quickly (e.g., almost real-time, etc.).

FIG. 4C illustrates a process 400C of performing a state estimate for a partitioned power grid, such as shown in FIG. 4B. Here, rather than estimate the state of the entire power grid using a sequence of equations, the example embodiments can use UKFs that are dedicated to particular partitions (i.e., trained from power measurements that are measured from its respective partition, etc.) Each partition 410, 420, and 430 may have its own UKF. Therefore, the state estimates for partitions 410, 420, and 430, can be performed in parallel on a multi-core processor 440. In particular, the UKF state estimation of partition 410 can be assigned to a first core, the UKF state estimation of partition 420 can be assigned to a second core, and the UKF state estimation of partition 430 can be assigned to a third core.

If the power grid continues to grow, the number of partitions can be updated (i.e., increased) to maintain a consistent number of loads in each partition with respect to a desired threshold (e.g., 200 loads, etc.) When the number of partitions increase, the number of cores used to perform the state estimation can be increased without adding additional time to the overall state estimation process.

According to various embodiments, the virtual elements (e.g., loads, voltage source, etc.) at boundary points are added to enforce power flow constraints, i.e., voltage equivalence at partitioning nodes and power out of a partition being the same as the power going in the neighboring partition. For example, the virtual element may be either voltage source or load.

In a general power grid, at each boundary between two partitions, virtual loads can be added in either partition at the boundary node to allow estimating the power flow states for the loads, which then provide resulting voltage outputs at the same loads. The voltage outputs are then used in the boundary conditions. For partitions that do not have any real voltage source, a virtual voltage source is added at one or more boundary nodes instead of virtual load. The virtual voltage source allows energizing that partition with estimated voltage states, which provides the resulting power flow at the node (i.e., converse of a virtual load). The virtual loads and virtual voltage sources are included in the augmented parameter vector (i.e., in addition to the original loads) for each partition. Thus, the augmented partition A is:

Φ_{A,k+1}=Φ_{A,k}+w_{A,k}

S_{A,k+1}=S_{A,k}+w_{A,k}^{S}

V_{A,k}=F_{A}(u_{A,k},Φ_{A,k},S_{A,k})

[symbol]

_{A,k}^{m}=h_{A}(u_{A,k},Φ_{A,k},S_{A,k}) Equation (9)

where w_{A,k} and w_{A,k}^{S} are zero mean normal process noise, v_{A,k} is zero mean measurement noise, [symbol] _{A,k}^{m} denotes the measured outputs, V_{A} is a vector representing magnitude and angle of A_{A,i} and S_{A}=[P(l_{A,i}), W(l_{A,i})]. F_{A} is a nonlinear function mapping states and inputs of partition A to the output VA. Similarly, partition B can be represented as:

Φ_{B,k+1}=Φ_{B,k}+w_{B,k}

V_{B,k+1}=V_{B,k}+w_{B,k}^{V}

S_{B,k}=F_{B}(u_{B,k},Φ_{B,k},V_{B,k})

[symbol]

_{B,k}^{m}=h_{B}(u_{B,k},Φ_{B,k},V_{B,k})+v_{B,k} Equation (10)

where w_{B,k} and W_{B,k}^{V} are zero mean normal process noise, v_{B,k} is zero mean measurement noise, [symbol] _{B,k}^{m} denotes the measured outputs, V_{B} is a vector representing magnitude and angle of) VS_{B,i′} and S_{B}=−[P(VS_{B,i′}), Q(VS_{B,i′})]. F_{B} is a nonlinear function mapping states and inputs of partition B to the output S_{B}. Note that, the size of the new states S_{A,k} and V_{B,k} depend on only the number of boundary buses between A and B are typically much smaller than the original states Φ_{A,k}, Φ_{B,k}. With the above augmented state space models for each partition, the boundary conditions in Equation (8) become:

V_{A,k}=V_{B,k}

S_{A,k}=S_{B,k} Equation (11)

For an augmented state space model including both partitions A and B, i.e. with X=[Φ_{A}, S_{A}, Φ_{B}, V_{B}], one can approach the overall state estimation of the full state vector X subject to the boundary constraints in Equation (11), following an approach of equality constrained Kalman filter. However, this is not desirable since the aim is to avoid performing estimation of the full state X for reasons of computational burden, scalability, large matrices and ill-conditioning that are the key challenge for centralized estimation as mentioned before. Instead, the individual UKFs in each partition A and B may be implemented to estimate only the corresponding local states X_{A}=[Φ_{A}; S_{A}] and X_{B}=[Φ_{B}; V_{B}], respectively, while jointly enforcing the common boundary constraints in Equation (11). This is done by including, in each partition's UKF, the boundary constraints as virtual measurements with mean and covariance. The proposed distributed estimation scheme runs unscented Kalman Filter update for each partition (which can run in parallel) and calculates the projected value for voltages and powers at coupling points between partitions.

Here, let Ŝ_{A,k}, Ŝ_{B,k}, \hat{V}_{A,k} and denote Kalman filter estimate of \hat{V}_{B,k} and S_{A,k} and S_{A,k}, S_{B,k}, V_{A,k} and V_{B,k}, respectively. Moreover, let associated covariance matrices be defined as

C_{A,k}^{S}:=E[(S_{A,k}−Ŝ_{A,k})(S_{A,k}−Ŝ_{A,k})′]

C_{B,k}^{S}:=E[(S_{B,k}−Ŝ_{B,k})(S_{B,k}−Ŝ_{B,k})′]

C_{A,k}^{V}:=E[(V_{A,k}−\hat{V}_{A,k})(V_{A,k}−\hat{V}_{A,k})′]

C_{B,k}^{V}:=E[(V_{B,k}−\hat{V}_{B,k})(V_{B,k}−\hat{V}_{B,k})′]

The projected estimate onto equality constraint in Eq 11 are calculated as

Ŝ_{A,k}^{p}=(C_{A,k}^{S}^{^{−1}}+C_{B,k}^{S}^{^{−1}})⁻¹C_{A,k}^{S}^{^{−1}}Ŝ_{A,k}(C_{A,k}^{S}^{^{−1}}+C_{B,k}^{S}^{^{−1}})⁻¹C_{B,k}^{S}^{^{−1}}Ŝ_{B,k} Equation (16)

\hat{V}_{B,k}^{p}=(C_{A,k}^{V}^{^{−1}}+C_{B,k}^{V}^{^{−1}})⁻¹C_{A,k}^{V}^{^{−1}}\hat{V}_{A,k}(C_{A,k}^{V}^{^{−1}}+C_{B,k}^{V}^{^{−1}})⁻¹C_{B,k}^{V}^{^{−1}}\hat{V}_{B,k} Equation (17)

and the corresponding projected covariance values are

Cₖ^{S}=(C_{A,k}^{S}^{^{−1}}+C_{B,k}^{S}^{^{−1}})⁻¹ Equation (18)

Cₖ^{V}=(C_{A,k}^{V}^{^{−1}}+C_{B,k}^{V}^{^{−1}})⁻¹ Equation (19)

The updated boundary condition voltages and power flows at sample k between partitions A and B are included (along with the real measurements in each partition) as virtual measurements with the mean value in Eq. 16-17, and measurement noise covariance in Eq. 18-19 for the next UKF sample (k+1) in the respective partitions. Note that there is a one-sample delay between the calculated updates on boundary conditions Eq 16-19, and their use in the UKF in next sample. To address this, the delay is explicitly modeled in each partition and the delay states are included in the state-space representation.

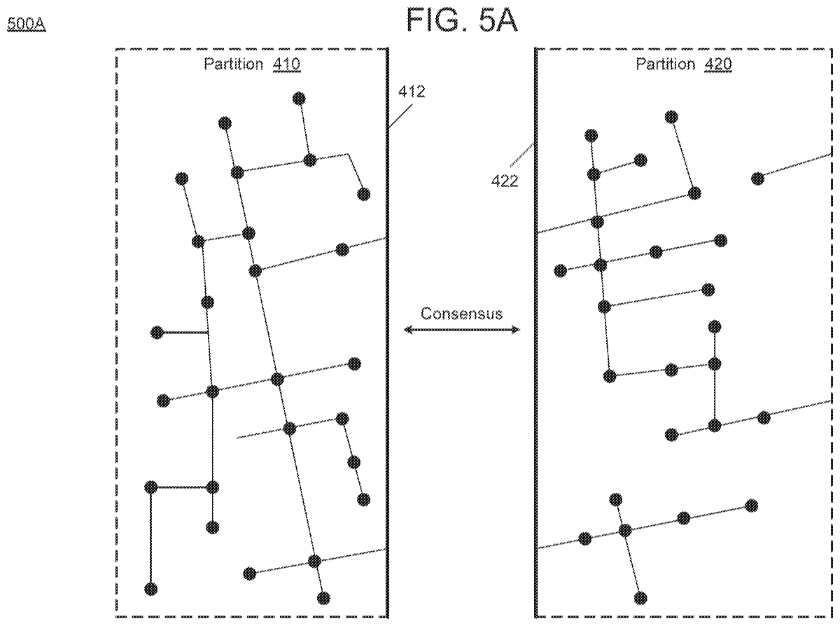

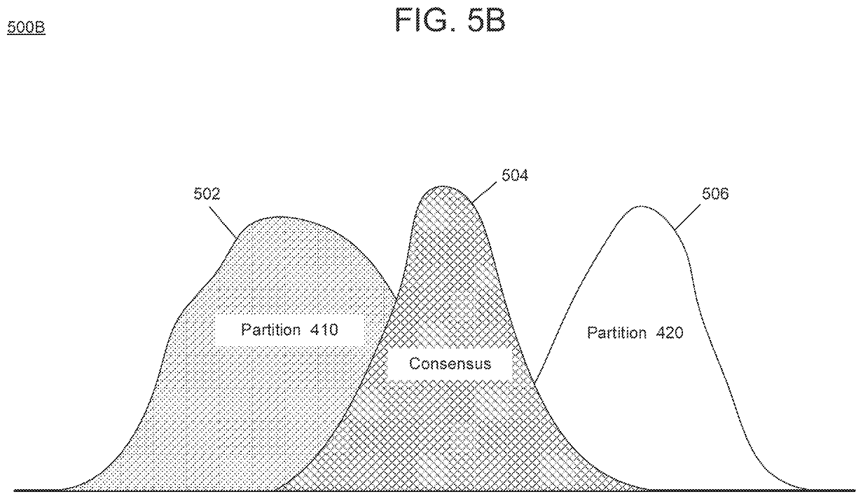

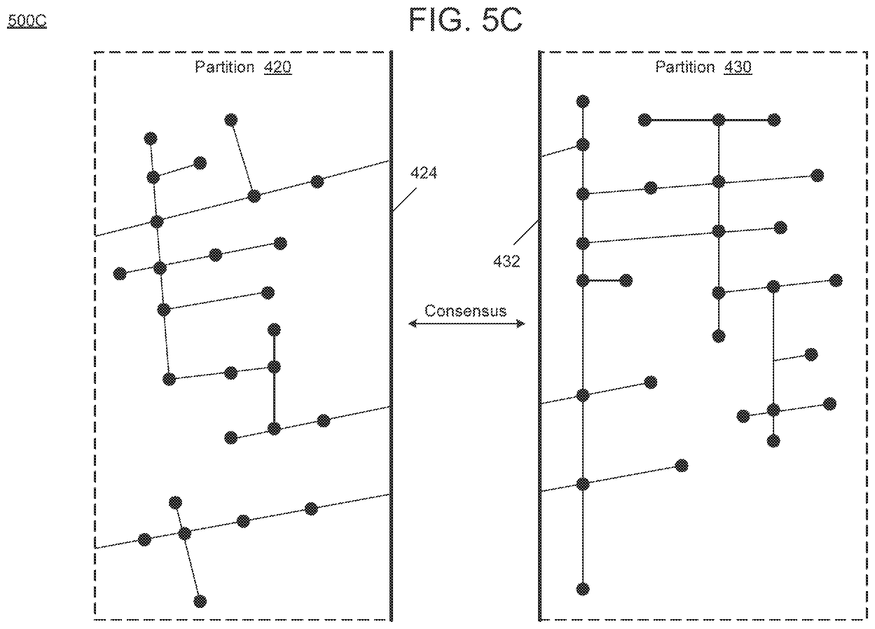

FIGS. 5A-5C illustrate a consensus process for a boundary state estimate in accordance with example embodiments. For example, the consensus process may be performed to resolve differences in boundary conditions between the partitions 410, 420, and 430 shown in FIGS. 4A-4C. For example, FIG. 5A illustrates a process 500A of performing a consensus for boundary voltages between the partition 410 and the partition 420. Here, partition 410 shares an outer boundary 412 with an outer boundary 422 of partition 420. In other words, the two partitions are adjacent to one another and interconnected by wires on the power grid. This same process may be performed for each two partitions that share a common boundary line.

Referring to FIG. 5A, a consensus system may receive boundary estimates (state estimates) from the partitions 410 and 420. Here, the boundary estimates may include voltage, active and reactive power flows, and the like. The consensus system will reconcile the estimated boundary conditions from the two partitions 410 and 420. FIG. 5B illustrates a view 500B of the boundary estimates for partition 410 and partition 420. Here, partition 410 is represented by wave 502 and partition 420 is represented by wave 506. In response to receiving the estimated boundary conditions from the partitions 410 and 420, the consensus system may determine mean values for each of the attributes such as voltage and power flow, and generate virtual measurement values for each of the partitions 410 and 420 to work towards in their next iteration of the state estimate of the boundary conditions. After a few iterations the estimated boundary conditions become more accurate as shown in wave 504 in FIG. 5B. Here, the wave 504 represents a consensus among the partitions 410 and 420.

FIG. 5C illustrates a process 500C of performing a boundary consensus between partitions 420 and 430. In particular, partition 420 shares an outer boundary 424 with an outer boundary 432 of the partition 430. The same consensus process that was performed in the examples of FIGS. 5A and 5B between partition 410 and partition 420 can be performed between partition 420 and partition 430.

The example embodiments provide a new distributed state estimation solution for estimation of unknown and varying loads in a large distribution grid. A key challenge in the distribution grid state estimation is the sheer size of the grid with thousands of parameters to estimate for each load's active and reactive power. While nonlinear Kalman filters are mature for such state estimation problems, a centralized Kalman filter is not practically viable for continuous online estimation due to the challenges in real-time execution of model, and the filter covariance and gain calculations. This motivated the need for a distributed estimation solution as described herein, wherein a larger grid is partitioned into smaller sections.

Furthermore, a UKF is used for state estimation in each section. Here, the sections can defined to be small enough to allow each partition's UKF to be practically implemented. The distributed estimation solution explicitly accounts for the boundary constraints for voltage and power flow continuity between the neighboring partitions. These constraints are enforced iteratively over time by calculating the common boundary conditions based on each partitions' current estimate, with their respective mean and covariance values, and including the updated boundary conditions as virtual measurements along with the real measurements in the individual partition UKF. As a non-limiting example, software for implementing the example embodiments may be installed on an IEEE 123 node.

As an example, a partitioning algorithm may be used to divide the overall grid into partitions such that the number of loads in each partition is within an acceptable min-max range. This ensures that each partition is roughly similar in size and the number of estimated states in each partition is manageable for UKF. The number of loads connected to each node may be used as an identifier of the node within a view/map. The goal is to partition the graph such that total nodes weights (i.e. the number of loads) are distributed almost equally and within the min-max range. In some embodiments, a Depth First Search (DFS) method may be performed. Here, the algorithm starts at the root node (in this case the feeder node) and explores as far as possible until it reaches the end of a branch and then back-tracks. As an example, a non-recursive version of the DFS may be used to traverse the graph. As the algorithm traverses the graph, it aggregates the number of loads observed on the way. As soon as the number passes a chosen threshold, the node is marked as the border of the first partition. Thereafter, the index for partition number is incremented and the DFS continues traversing the graph from that node for the updated partition index. If it reaches the end of a branch and needs to backtrack, or exceeds the threshold, it increments the partition index to the next one and continues. This process is continued until the entire graph G has been traversed. Finally, a finishing step is done to identify any partitions that are too small (below the min load count threshold), which are then merged with the adjacent partition.

Meanwhile, the consensus process may rely on an equality constrained Kalman filter. The expected value of the shared power and voltages are updated according to equality constrained Kalman filter. For example, let Xₖ=[Φ_{A,k}, S_{A,k}, Φ_{B,k}, V_{B,k}] denote the lumped state vector of the two partitions and posterior estimate of aggregated states be \hat{X}. Let d denote the difference between two quantities at each partition that are subject to equality constraints, i.e., equality constraint vector that is constrained to zero and \hat{d} denote the estimated value based on \hat{X}. The following can also be define:

Cₖ^{xx}:=E[X̅ₖX̅′ₖ]

Cₖ^{dd}:=E[d̅ₖd̅′ₖ]

Cₖ^{xd}:=E[X̅ₖd̅′ₖ]

Kₖ^{p}:=Cₖ^{xd}(Cₖ^{dd})⁻¹ Equations(20)-(23)

Where X̅ₖ:Xₖ−\hat{X}ₖ and d̅ₖ=dₖ−\hat{d}ₖ. Note that these expectations are conditioned to observation up to time l [symbol] ₖ that is omitted with abuse of notation. The projection of estimated states onto constrained manifold provides constrained Kalman filter estimate that is calculated as follows:

\hat{X}ₖ^{p}=\hat{X}ₖ−Kₖ^{p}\hat{d}ₖ Equation (24)

and the covariance of the projected estimated is

Cₖ^{xxp}=E[(Xₖ−\hat{X}ₖ^{p})(Xₖ−\hat{X}ₖ^{p})′]=Cₖ^{xx}−Kₖ^{p}Cₖ^{dd}Kₖ^{p}′ Equation (25)

Considering dₖ=S_{A,k}−S_{B,k} and independence of the two partitions, there is provided

Cₖ^{dd}=E[(S̅_{A,k}−S̅_{B,k})(S̅_{A,k}−S̅_{B,k})′]=E[S̅_{A,k}S̅′_{A,k}]+E[S̅_{B,k}S̅′_{B,k}]=C_{A,k}^{S}+C_{B,k}^{S} Equation (26)

Where C_{A,k}^{S} and C_{B,k}^{k} are covariance matrices. Moreover, considering the independence of the random variables of the two partitions, there is provided

Cₖ^{xd}=[E[[Φ̅′_{A,k}S̅′_{A,k}]′S̅_{A,k}]′,−[E[[Φ̅′_{B,k}S̅′_{B,k}]′S̅_{B,k}]′. Equation (27)

According to the projection update in Equation (24), the state S_{A} of partition A is updated as

$${\hat{S}}_{A , k}^{p} = {\hat{S}}_{A , k} - {{C}_{A , k}^{S} ( {C}_{A , k}^{S} + {C}_{B , k}^{S} )}^{- 1} ( {\hat{S}}_{A , k} - {\hat{S}}_{B , k} ) = {{C}_{B , k}^{S} ( {C}_{A , k}^{S} + {C}_{B , k}^{S} )}^{- 1} {\hat{S}}_{A , k} + {{C}_{A , k}^{S} ( {C}_{A , k}^{S} + {C}_{B , k}^{S} )}^{- 1} {\hat{S}}_{B , k} = {( {{C}_{A , k}^{S}}^{- 1} + {{C}_{B , k}^{S}}^{- 1} )}^{- 1} {{C}_{A , k}^{S}}^{- 1} {\hat{S}}_{A , k}$$

Where the last equality is using the matrix equality Z(Z+Y)⁻¹=(Z⁻¹+Y⁻¹)⁻¹Y⁻¹. Considering the block diagonal element of covariance projected estimated in Equation (25) corresponding with E[(S_{A,k}−Ŝ^{p}_{A,k})(S_{A,k}−Ŝ^{p}_{A,k})′], there is provided

$$\begin{matrix}{C}_{k}^{S} : = E [ ( {S}_{A , k} - {\hat{S}}_{A , k}^{p} ) {( {S}_{A , k} - {\hat{S}}_{A , k}^{p} )}^{′} ] \\ = {C}_{A , k}^{S} - {{C}_{A , k}^{S} ( {C}_{A , k}^{S} + {C}_{B , k}^{S} )}^{- 1} {C}_{A , k}^{S} \\ = {{C}_{A , k}^{S} ( {C}_{A , k}^{S} + {C}_{B , k}^{S} )}^{- 1} {C}_{B , k}^{S} \\ = {( {{C}_{A , k}^{S}}^{- 1} + {{C}_{B , k}^{S}}^{- 1} )}^{- 1}\end{matrix} \qquad Equation ( 29 )$$

Equations (28) and (29) provide a projected estimate and covariance for the state SA in partition A after Kalman filter update for the new measurements is performed for each partition separately. Following the same procedure, the projection update for state VB in partition B can be determined based on Equation (17) and the projected covariance can be determined based on Equation (19).

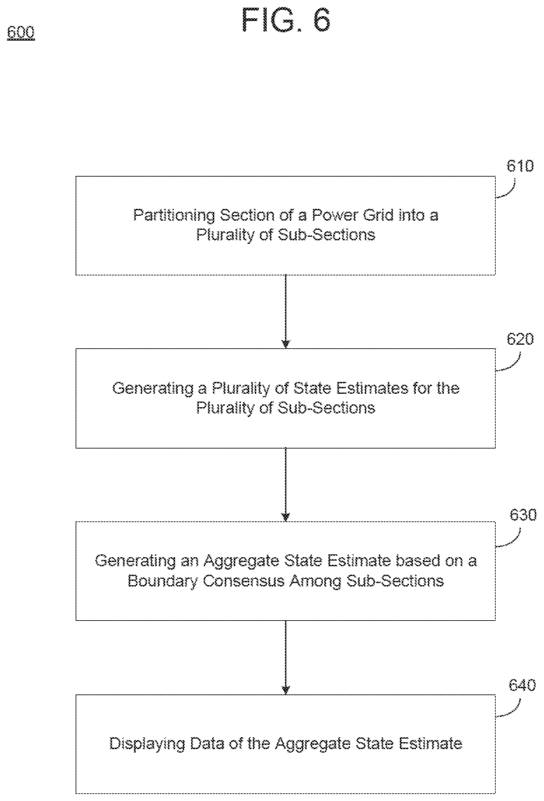

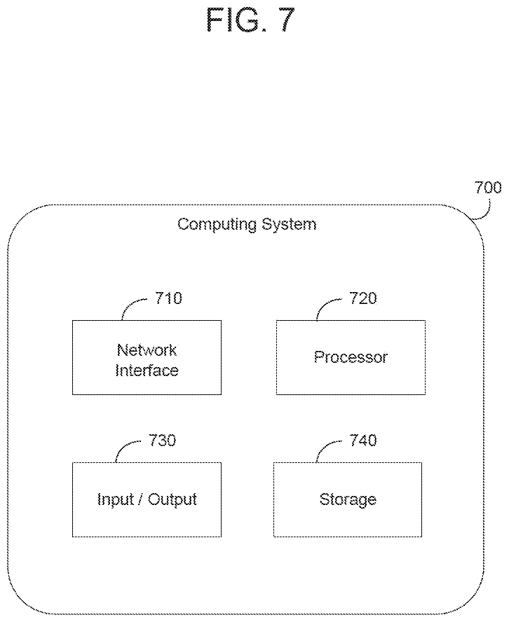

FIG. 6 illustrates a method 600 of a partitioning a state estimation process in accordance with an example embodiment. For example, the method 600 may be performed by a computing system such as shown in FIG. 7. The computing system may include a web server, a cloud platform, a personal computer, a mobile device, a control center, or the like. Referring to FIG. 6, in 610, the method may include partitioning a section of the power distribution grid into a plurality of sub-sections based on loads distributed within the section of the power distribution grid. For example, the partitioning may be performed in response to an input by an operator on a user interface of a control center for the power grid.

In 620, the method may include generating a plurality of state estimates for the plurality of sub-sections based on load distribution within the plurality of sub-sections and an unscented Kalman Filter model. In 630, the method may include generating an aggregate state estimate for the section of the power distribution grid based on an aggregate of the plurality of state estimates for the plurality of sub-sections and a boundary consensus between the plurality of sub-sections from a previous state estimation of the section of the power distribution grid. In 640, the method include displaying data about the aggregate state estimate via a user interface.

In some embodiments, the partitioning may include partitioning the section of the power distribution grid into a plurality of non-overlapping sub-sections that each include a unique subset of loads on the power distribution grid. In some embodiments, the plurality of state estimates are generated by a plurality of local unscented Kalman Filter models, respectively, which are trained based on local state and power measurements of the plurality of sub-sections. In some embodiments, the method may further include executing a consensus process between two adjacent sub-sections in the power grid which share a common boundary.

In some embodiments, the method may further include receiving voltage estimates and variance estimates of the common boundary from each of the two adjacent sub-sections during an iteration of a state estimate for the section of the power distribution grid. In some embodiments, the generating the aggregate state estimate may include determining a mean value of the received voltage estimates of the iteration of the state estimate and setting a pseudo voltage value and pseudo variance value of the common boundary to be used during a state estimate of the section of the power distribution grid during a next iteration of the state estimate for the section of the power grid. In some embodiments, the partitioning may include partitioning the power distribution grid such that each sub-section from among the plurality of sub-sections of the power distribution grid includes less than a predetermined threshold of loads.

FIG. 7 illustrates a computing system 700 that may be used in any of the methods and processes described herein, in accordance with an example embodiment. For example, the computing system 700 may be a database node, a server, a cloud platform, or the like. In some embodiments, the computing system 700 may be distributed across multiple computing devices such as multiple database nodes. Referring to FIG. 7, the computing system 700 includes a network interface 710, a processor 720, an input/output 730, and a storage device 740 such as an in-memory storage, and the like. Although not shown in FIG. 7, the computing system 700 may also include or be electronically connected to other components such as a display, an input unit(s), a receiver, a transmitter, a persistent disk, and the like. The processor 720 may control the other components of the computing system 700.

The network interface 710 may transmit and receive data over a network such as the Internet, a private network, a public network, an enterprise network, and the like. The network interface 710 may be a wireless interface, a wired interface, or a combination thereof. The processor 720 may include one or more processing devices each including one or more processing cores. In some examples, the processor 720 is a multicore processor or a plurality of multicore processors. Also, the processor 720 may be fixed or it may be reconfigurable. The input/output 730 may include an interface, a port, a cable, a bus, a board, a wire, and the like, for inputting and outputting data to and from the computing system 700. For example, data may be output to an embedded display of the computing system 700, an externally connected display, a display connected to the cloud, another device, and the like. The network interface 710, the input/output 730, the storage 740, or a combination thereof, may interact with applications executing on other devices.

The storage device 740 is not limited to a particular storage device and may include any known memory device such as RAM, ROM, hard disk, and the like, and may or may not be included within a database system, a cloud environment, a web server, or the like. The storage 740 may store software modules or other instructions which can be executed by the processor 720 to perform the method shown in FIG. 9. According to various embodiments, the storage 740 may include a data store having a plurality of tables, records, partitions and sub-partitions. The storage 740 may be used to store database records, documents, entries, and the like.

As will be appreciated based on the foregoing specification, the above-described examples of the disclosure may be implemented using computer programming or engineering techniques including computer software, firmware, hardware or any combination or subset thereof. Any such resulting program, having computer-readable code, may be embodied or provided within one or more non-transitory computer-readable media, thereby making a computer program product, i.e., an article of manufacture, according to the discussed examples of the disclosure. For example, the non-transitory computer-readable media may be, but is not limited to, a fixed drive, diskette, optical disk, magnetic tape, flash memory, external drive, semiconductor memory such as read-only memory (ROM), random-access memory (RAM), and/or any other non-transitory transmitting and/or receiving medium such as the Internet, cloud storage, the Internet of Things (IoT), or other communication network or link. The article of manufacture containing the computer code may be made and/or used by executing the code directly from one medium, by copying the code from one medium to another medium, or by transmitting the code over a network.

The computer programs (also referred to as programs, software, software applications, “apps”, or code) may include machine instructions for a programmable processor, and may be implemented in a high-level procedural and/or object-oriented programming language, and/or in assembly/machine language. As used herein, the terms “machine-readable medium” and “computer-readable medium” refer to any computer program product, apparatus, cloud storage, internet of things, and/or device (e.g., magnetic discs, optical disks, memory, programmable logic devices (PLDs)) used to provide machine instructions and/or data to a programmable processor, including a machine-readable medium that receives machine instructions as a machine-readable signal. The “machine-readable medium” and “computer-readable medium,” however, do not include transitory signals. The term “machine-readable signal” refers to any signal that may be used to provide machine instructions and/or any other kind of data to a programmable processor.

The above descriptions and illustrations of processes herein should not be considered to imply a fixed order for performing the process steps. Rather, the process steps may be performed in any order that is practicable, including simultaneous performance of at least some steps. Although the disclosure has been described in connection with specific examples, it should be understood that various changes, substitutions, and alterations apparent to those skilled in the art can be made to the disclosed embodiments without departing from the spirit and scope of the disclosure as set forth in the appended claims.

What is claimed is:

1. A computing system comprising:
a memory configured to store load data from a power distribution grid; and
a processor configured to
partition a section of the power distribution grid into a plurality of sub-sections based on loads distributed within the section of the power distribution grid;
generate a plurality of state estimates for the plurality of sub-sections based on load distribution within the plurality of sub-sections and an Kalman Filter model; and
generate an aggregate state estimate for the section of the power distribution grid based on an aggregate of the plurality of state estimates for the plurality of sub-sections and a boundary consensus between the plurality of sub-sections from a previous state estimation of the section of the power distribution grid; and
display data about the aggregate state estimate via a user interface.

2. The computing system of claim 1, wherein the processor is configured to partition the section of the power distribution grid into a plurality of non-overlapping sub-sections that each include a unique subset of loads on the power distribution grid.

3. The computing system of claim 1, wherein the processor is configured to generate the plurality of state estimates via a plurality of local unscented Kalman Filter estimators, respectively, which are computed based on local state and power measurements of the plurality of sub-sections.

4. The computing system of claim 1, wherein the processor is further configured to execute a consensus process between two adjacent sub-sections in the power grid which share a common boundary.

5. The computing system of claim 4, wherein the processor is further configured to receive voltage estimates, power flow estimates, and variance estimates of the common boundary from each of the two adjacent sub-sections during an iteration of a state estimate for the section of the power distribution grid.

6. The computing system of claim 5, wherein the processor is configured to determine a mean value of the received voltage and power flow estimates of the iteration of the state estimate and set a pseudo voltage value and pseudo variance value of the common boundary to be used during a state estimate of the section of the power distribution grid during a next iteration of the state estimate for the section of the power grid.

7. The computing system of claim 1, wherein the processor is configured to partition the power distribution grid such that each sub-section from among the plurality of sub-sections of the power distribution grid includes less than a predetermined threshold of loads.

8. A method comprising:
partitioning a section of the power distribution grid into a plurality of sub-sections based on loads distributed within the section of the power distribution grid;
generating a plurality of state estimates for the plurality of sub-sections based on load distribution within the plurality of sub-sections and a Kalman Filter model; and
generating an aggregate state estimate for the section of the power distribution grid based on an aggregate of the plurality of state estimates for the plurality of sub-sections and a boundary consensus between the plurality of sub-sections from a previous state estimation of the section of the power distribution grid; and
displaying data about the aggregate state estimate via a user interface.

9. The method of claim 8, wherein the partitioning comprises partitioning the section of the power distribution grid into a plurality of non-overlapping sub-sections that each include a unique subset of loads on the power distribution grid.

10. The method of claim 8, wherein the plurality of state estimates are generated by a plurality of local unscented Kalman Filter estimators, respectively, which are computed based on local state and power measurements of the plurality of sub-sections.

11. The method of claim 8, wherein the method further comprises executing a consensus process between two adjacent sub-sections in the power grid which share a common boundary.

12. The method of claim 11, wherein the method further comprises receiving voltage estimates, power flow estimates, and variance estimates of the common boundary from each of the two adjacent sub-sections during an iteration of a state estimate for the section of the power distribution grid.

13. The method of claim 12, wherein the generating the aggregate state estimate comprises determining a mean value of the received voltage and power flow estimates of the iteration of the state estimate and setting a pseudo voltage value and pseudo variance value of the common boundary to be used during a state estimate of the section of the power distribution grid during a next iteration of the state estimate for the section of the power grid.

14. The method of claim 8, wherein the partitioning comprises partitioning the power distribution grid such that each sub-section from among the plurality of sub-sections of the power distribution grid includes less than a predetermined threshold of loads.

15. A non-transitory computer-readable storage medium comprising instructions which when executed by a processor cause a computer to perform a method comprising:
partitioning a section of the power distribution grid into a plurality of sub-sections based on loads distributed within the section of the power distribution grid;
generating a plurality of state estimates for the plurality of sub-sections based on load distribution within the plurality of sub-sections and a Kalman Filter model; and
generating an aggregate state estimate for the section of the power distribution grid based on an aggregate of the plurality of state estimates for the plurality of sub-sections and a boundary consensus between the plurality of sub-sections from a previous state estimation of the section of the power distribution grid; and
displaying data about the aggregate state estimate via a user interface.

16. The non-transitory computer-readable medium of claim 15, wherein the partitioning comprises partitioning the section of the power distribution grid into a plurality of non-overlapping sub-sections that each include a unique subset of loads on the power distribution grid.

17. The non-transitory computer-readable medium of claim 15, wherein the plurality of state estimates are generated by a plurality of local unscented Kalman Filter estimators, respectively, which are computed based on local state and power measurements of the plurality of sub-sections.

18. The non-transitory computer-readable medium of claim 15, wherein the method further comprises executing a consensus process between two adjacent sub-sections in the power grid which share a common boundary.

19. The non-transitory computer-readable medium of claim 18, wherein the method further comprises receiving voltage estimates, power flow estimates, and variance estimates of the common boundary from each of the two adjacent sub-sections during an iteration of a state estimate for the section of the power distribution grid.

20. The non-transitory computer-readable medium of claim 15, wherein the partitioning comprises partitioning the power distribution grid such that each sub-section from among the plurality of sub-sections of the power distribution grid includes less than a predetermined threshold of loads.
